(19) United States
(12) Patent Application Publication
(10) Pub. No.: US 2025/0166980 A1
(43) Pub. Date: May 22, 2025

(54) PLASMA PROCESSING METHOD AND PLASMA PROCESSING APPARATUS

(71) Applicant: Tokyo Electron Limited, Tokyo (JP)

(72) Inventors: Yusuke SHIMIZU, Gyeonggi-do (KR); Satoru NAKAMURA, Miyagi (JP); Toshihisa OZU, Miyagi (JP); Naoki MATSUMOTO, Miyagi (JP)

(73) Assignee: Tokyo Electron Limited, Tokyo (JP)

(21) Appl. No.: 19/033,080

(22) Filed: Jan. 21, 2025

Related U.S. Application Data
(63) Continuation of application No. PCT/JP2023/026370, filed on Jul. 19, 2023.

(30) Foreign Application Priority Data
Jul. 22, 2022 (JP) 2022-117412
Jul. 22, 2022 (JP) 2022-117420
Jul. 22, 2022 (JP) 2022-117500

(51) Int. Cl. H01J 37/32

(52) U.S. Cl. CPC H01J 37/32963; H01J 37/32724; H01J 2237/334

(57) ABSTRACT

Provided is a technique for grasping the state of plasma processing. A plasma processing method is a method for generating plasma in a chamber to executing plasma processing on a substrate in a plasma processing apparatus having the chamber and a substrate support disposed in the chamber, the method including (a) placing the substrate on the substrate support, (b) generating plasma in the chamber to execute the plasma processing on the substrate on the substrate support, (c) acquiring data related to ion flux generated between the plasma generated in the chamber and the substrate placed on the substrate support in the (b), and (d) detecting an end point of the plasma processing based on the data.

### CROSS-REFERENCE TO RELATED APPLICATIONS

This application is a bypass continuation application of international application No. PCT/JP2023/026370 having an international filing date of Jul. 19, 2023, and designating the United States, the international application being based upon and claiming the benefit of priority from Japanese Patent Applications No. 2022-117412, No. 2022-117420, and No. 2022-117500 filed on Jul. 22, 2022, the entire contents of each are incorporated herein by reference.

### TECHNICAL FIELD

Exemplary embodiments of the present disclosure relate to a plasma processing method and a plasma processing apparatus.

### BACKGROUND

Plasma processing apparatuses for processing substrates using plasma include those described in JPH11-233492A, JP2003-282546A, and JP2010-109350A.

JPH11-233492A discloses that an end point of plasma processing is detected based on a change in an emission spectrum transmitted through a detection window disposed at a sidewall of a processing chamber of a plasma processing apparatus.

JP2003-282546A discloses an on-wafer monitoring system that measures plasma on a wafer surface.

JP2010-109350A discloses a technique for detecting an error in a placement state when a substrate is placed on a substrate placement table and processed while being heated.

### CITATION LIST

### Patent Documents

Patent Literature 1: JPH11-233492A
Patent Literature 2: JP2003-282546A
Patent Literature 3: JP2010-109350A

### SUMMARY

The present disclosure provides a technique for grasping a state of plasma processing.

A plasma processing method according to one or more embodiments of the present disclosure is a plasma processing method for generating plasma in a chamber to execute plasma processing on a substrate in a plasma processing apparatus having the chamber and a substrate support disposed in the chamber, the method including (a) placing the substrate on the substrate support, (b) generating plasma in the chamber to execute the plasma processing on the substrate on the substrate support, (c) acquiring data related to ion flux generated between the plasma generated in the chamber and the substrate placed on the substrate support in the (b), and (d) detecting an end point of the plasma processing based on the data.

According to one or more embodiments of the present disclosure, it is possible to provide a technique for grasping a state of plasma processing.

### BRIEF DESCRIPTION OF DRAWINGS

FIG. 1 is a diagram illustrating an example of a configuration of a plasma processing system.

FIG. 2 illustrates an example of the configuration of a capacitively coupled plasma processing apparatus.

FIG. 3 shows an example of the upper surface of a substrate support 11.

FIG. 4 shows an example of a cross section of the substrate support 11.

FIG. 5 is a block diagram showing an example of the configuration of a control substrate 80.

FIG. 5A is a diagram illustrating an example of a configuration of a substrate processing system.

FIG. 6 is a flowchart showing a method according to one or more embodiments.

FIG. 7 shows an example of distribution data.

FIG. 8 is a diagram showing an example of etching a film on a substrate.

FIG. 9 is a graph showing an example of the temporal change in the value of distribution data of ion flux.

FIG. 10 is a flowchart showing a method according to one or more embodiments.

FIG. 11 shows an example of distribution data.

FIG. 12 shows an example of distribution data.

FIG. 13 is a flowchart showing a method according to one or more embodiments.

FIG. 14 is a flowchart showing the present method.

FIG. 15 is a schematic diagram showing an example of a first temperature distribution.

FIG. 16A is a schematic diagram showing an example of a substrate W during the processing in step ST2.

FIG. 16B is a schematic diagram showing an example of the substrate W after the processing in step ST2 is performed.

FIG. 17 is a schematic diagram showing an example of a second temperature distribution.

FIG. 18 is a diagram showing an example of a method of detecting mis-alignment of a substrate.

FIG. 19 is a flowchart showing an example of step ST5.

FIG. 20 is a schematic diagram showing an example of the substrate W after the processing in step ST51 is performed.

FIG. 21 is a schematic diagram showing an example of the substrate W after the processing in step ST52 is performed.

FIG. 22A is a schematic diagram showing an example of the substrate W during the processing in step ST53.

FIG. 22B is a schematic diagram showing an example of the substrate W after the processing in step ST53 is performed.

FIG. 23 is a schematic diagram showing an example of the temperature distribution in a central region 111a immediately after the substrate W is re-placed in step ST53.

FIG. 24 is a flowchart showing an example of step ST6.

FIG. 25 is a flowchart showing another example of the present method.

### DETAILED DESCRIPTION

An embodiment of the present disclosure will be described below.

In one or more embodiments, there is provided a plasma processing method for generating plasma in a chamber to execute plasma processing on a substrate in a plasma processing apparatus having the chamber and a substrate support disposed in the chamber, the method including (a) placing the substrate on the substrate support, (b) generating plasma in the chamber to execute the plasma processing on the substrate on the substrate support, (c) acquiring data related to ion flux generated between the plasma generated in the chamber and the substrate placed on the substrate support in the (b), and (d) detecting an end point of the plasma processing based on the data.

In one or more embodiments, the data related to the ion flux is data related to distribution of the ion flux.

In one or more embodiments, the plasma processing includes etching processing for etching a film formed on the substrate, and an end point of the etching processing is detected in the (d).

In one or more embodiments, the (c) includes (c-1) supplying power to each of a plurality of heaters disposed in the substrate support, (c-2) acquiring the power supplied to each of the plurality of heaters in a state in which the plasma is generated in the chamber, and (c-3) calculating the data based on the power acquired for each of the plurality of heaters in the (c-2).

In one or more embodiments, the substrate support has a substrate supporting surface configured to support the substrate, the substrate support surface has multiple support regions, and the multiple heaters are disposed in the substrate support in the respective multiple support regions.

In one or more embodiments, there is provided a plasma processing apparatus including a chamber, a substrate support disposed in the chamber, and a controller configured to execute processing for (a) placing a substrate on the substrate support, (b) generating plasma in the chamber to execute plasma processing on the substrate on the substrate support, (c) acquiring data related to ion flux generated between the plasma generated in the chamber and the substrate placed on the substrate support in the (b), and (d) detecting an end point of the plasma processing based on the data.

In one or more embodiments, there is provided a plasma processing method for generating plasma in a chamber to execute plasma processing on a substrate in a plasma processing apparatus having the chamber and a substrate support disposed in the chamber, the method including (a) placing the substrate on the substrate support, (b) generating plasma in the chamber to execute the plasma processing on the substrate on the substrate support, and (c) acquiring distribution data that is data related to distribution of ion flux generated between the plasma and the substrate placed on the substrate support during a transitional period in which a state of the plasma generated in the chamber changes.

In one or more embodiments, the plasma processing method further includes (d) determining whether there is an error in the state of the plasma during the transitional period based on the distribution data.

In one or more embodiments, in the (d), a location where the error is found in the state of the plasma during the transitional period is identified based on the distribution data.

In one or more embodiments, in the (c), a temporal change of the distribution data is acquired.

In one or more embodiments, the transitional period includes at least one of start of plasma generation and switching between the steps of plasma processing.

In one or more embodiments, the (c) includes (c-1) supplying power to each of a plurality of heaters disposed in the substrate support, (c-2) acquiring the power supplied to each of the plurality of heaters in a state in which the plasma is generated in the chamber, and (c-3) calculating the distribution data based on the power acquired for each of the plurality of heaters in the (c-2).

In one or more embodiments, the substrate support has a substrate supporting surface configured to support the substrate, the substrate support surface has multiple support regions, and the multiple heaters are disposed in the substrate support in the respective multiple support regions.

In one or more embodiments, there is provided a plasma processing apparatus including a chamber, a substrate support disposed in the chamber, and a controller configured to execute processing for (a) placing a substrate on the substrate support, (b) generating plasma in the chamber to execute plasma processing on the substrate on the substrate support, and (c) acquiring distribution data that is data related to a distribution of ion flux generated between the plasma and the substrate placed on the substrate support during a transitional period in which a state of the plasma generated in the chamber changes.

An embodiment of the present disclosure will be described below in detail with reference to the drawings. In the drawings, the same or similar elements have the same reference characters, and duplicated descriptions thereof will be omitted. Unless otherwise specified, the upward-downward positional relationship, the rightward/leftward positional relationship, and other positional relationship will be described based on the positional relationships shown in the drawings. The dimensional ratios in the drawings are not equal to actual ratios, and the actual ratios are not limited to the ratios shown in the drawings.

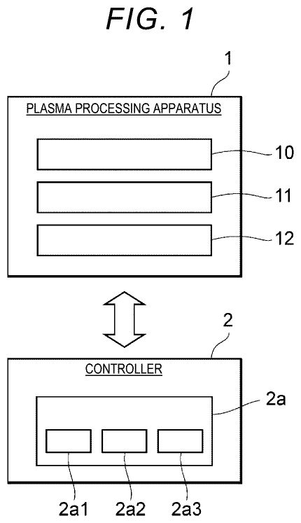

FIG. 1 is a diagram illustrating an example of a configuration of a plasma processing system. In one or more embodiments, the plasma processing system includes a plasma processing apparatus 1 and a controller 2. The plasma processing system is an example of a substrate processing system, and the plasma processing apparatus 1 is an example of the substrate processing apparatus. The plasma processing apparatus 1 includes a plasma processing chamber (also simply referred to as “chamber”) 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Furthermore, various types of plasma generators, including an alternating current (AC) plasma generator and a direct current (DC) plasma generator, may be used. In one or more embodiments, an AC signal (AC power) used by the AC plasma generator has a frequency within a range from 100 kHz to 10 GHz. The AC signal therefore includes a radio frequency (RF) signal and a microwave signal. In one or more embodiments, the RF signal has a frequency within a range from 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein. In one or more embodiments, a portion or the entirety of the controller 2 may be provided in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

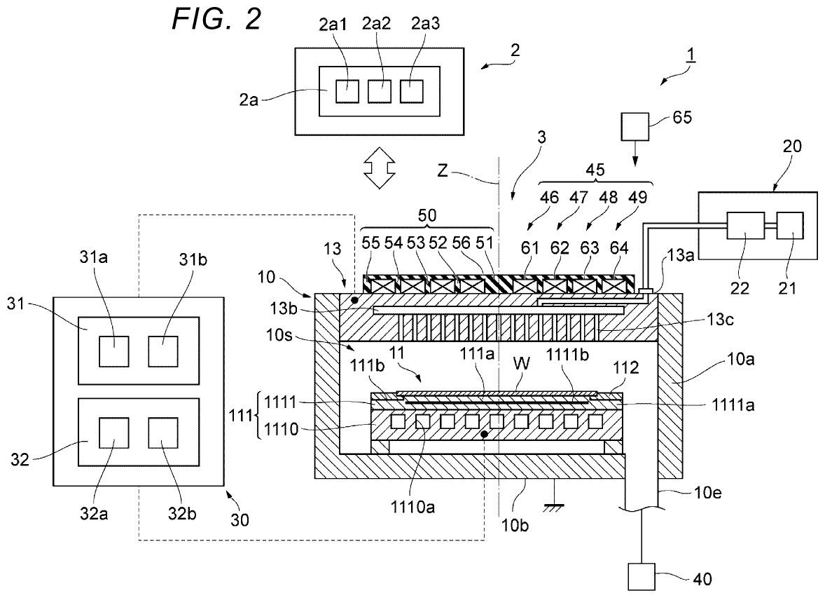

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one or more embodiments, the shower head 13 constitutes at least a portion of the ceiling of the plasma processing chamber 10. The plasma processing chamber 10 has a plasma processing space 10s defined by the shower head 13, a sidewall 10a and a bottom wall 10b of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is placed on the central region 111a of the main body 111, and the ring assembly 112 is disposed on the annular region 111b of the main body 111 so as to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one or more embodiments, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one or more embodiments, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power source 31 and/or a DC power source 32, which will be described later, may be disposed in the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one or more embodiments, the one or more annular members include one or more edge rings and at least one cover ring. The edge ring is formed of a conductive material or an insulating material, and the cover ring is formed of an insulating material.

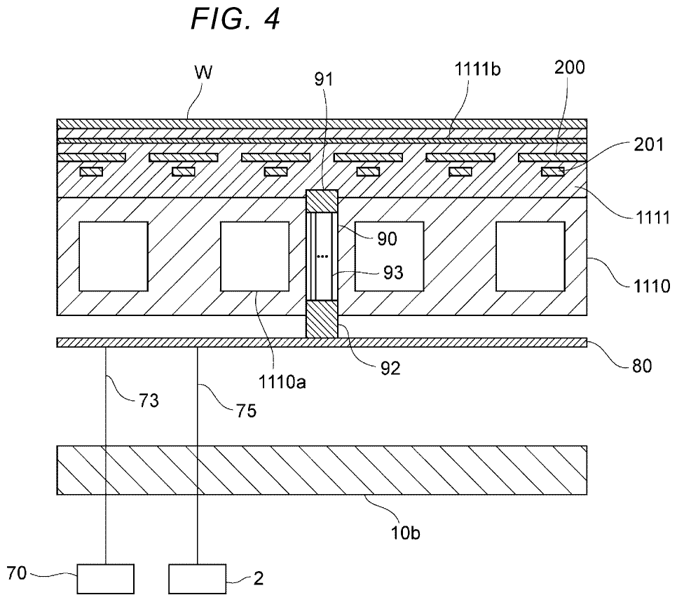

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one or more embodiments, the flow path 1110a is formed in the base 1110, and one or more heaters are disposed in the ceramic member 1111a of the electrostatic chuck 1111. The substrate support 11 may further include a heat transferring gas supply configured to supply a heat transferring gas to the gap between the rear surface of the substrate W and the central region 111a. The temperature controlling module will be described later in detail with reference to FIG. 4.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s via the gas introduction ports 13c. The shower head 13 further includes at least one upper electrode. The gas introduction unit may include, in addition to the shower head 13, one or more side gas injectors (SGI) that are attached to one or more openings formed in the sidewall 10a.

The gas supply 20 may include at least one gas source 21 and at least one flow rate controller 22. In one or more embodiments, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes an RF power source 31 coupled to plasma processing chamber 10 via at least one impedance matching circuit. The RF power source 31 is configured to supply at least one RF signal (RF power) to the at least one lower electrode and/or the at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one or more embodiments, the RF power source 31 includes a first RF generator 31a and a second RF generator 31b. The first RF generator 31a is coupled to the at least one lower electrode and/or the at least one upper electrode via the at least one impedance matching circuit, and configured to generate a source RF signal (source RF power) for plasma generation. In one or more embodiments, the source RF signal has a frequency within a range from 10 MHz to 150 MHz. In one or more embodiments, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one or more embodiments, the bias RF signal has a frequency lower than the frequency of the source RF signal. In one or more embodiments, the bias RF signal has a frequency within a range from 100 kHz to 60 MHz. In one or more embodiments, the second RF generator 31b may be configured to generate a plurality of bias RF signals having different frequencies. The generated one or more bias RF signals are supplied to the at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one or more embodiments, the first DC generator 32a is connected to at least one lower electrode and configured to generate a first DC signal. The generated first DC signal is applied to at least one lower electrode. In one or more embodiments, the second DC generator 32b is connected to at least one upper electrode and configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular waveform or a combination thereof. In one or more embodiments, a waveform generator that generates a sequence of voltage pulses from a DC signal is connected between the first DC generator 32a and the at least one lower electrode. Accordingly, the first DC generator 32a and the waveform generator configure a voltage pulse generator. When the second DC generator 32b and the waveform generator constitute the voltage pulse generator, the voltage pulse generator is connected to the at least one upper electrode. The voltage pulse may have a positive polarity or a negative polarity. The sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

The plasma processing apparatus 1 includes an electromagnet assembly 3 that includes one or more electromagnets 45. The electromagnet assembly 3 is configured to generate a magnetic field in the chamber 10. In one or more embodiments, the plasma processing apparatus 1 includes an electromagnet assembly 3 including multiple electromagnets 45. In the embodiment shown in FIG. 2, the plurality of electromagnets 45 include electromagnets 46 to 49. The multiple electromagnets 45 are provided on or above the chamber 10. That is, the electromagnet assembly 3 is disposed on or above the chamber 10. In the example shown in FIG. 2, the plurality of electromagnets 45 are provided on the shower head 13.

The one or more electromagnets 45 each include a coil. In FIG. 2, the electromagnets 46 to 49 include coils 61 to 64. The coils 61 to 64 are wound around a center axis Z. The center axis Z may be an axis passing through the center of the substrate W or the substrate support 11. That is, in the electromagnet assembly 3, the coils 61 to 64 may each be a toroidal coil. The coils 61 to 64 are provided coaxially around the center axis Z at the same height position.

The electromagnet assembly 3 further includes a bobbin 50 (or yoke). The coils 61 to 64 are wound around the bobbin 50 (or yoke). The bobbin 50 is made, for example, of a magnetic material. The bobbin 50 has a columnar section 51, multiple cylindrical sections 52 to 55, and a base section 56. The base section 56 has a substantially disk-like shape, and the center axis thereof coincides with the center axis Z. The columnar section 51 and the multiple cylindrical sections 52 to 55 extend downward from the lower surface of the base section 56. The columnar section 51 has a substantially circular columnar shape, and the center axis thereof substantially coincides with the center axis Z. The radius of the columnar section 51 is, for example, 30 mm. The cylindrical sections 52 to 55 extend around the center axis Z outside the columnar section 51.

The coil 61 is wound along the outer circumferential surface of the columnar section 51 and housed in a groove between the columnar section 51 and the cylindrical section 52. The coil 62 is wound along the outer circumferential surface of the cylindrical section 52 and housed in a groove between the cylindrical section 52 and the cylindrical section 53. The coil 63 is wound along the outer circumferential surface of the cylindrical section 53 and housed in a groove between the cylindrical section 53 and the cylindrical section 54. The coil 64 is wound along the outer circumferential surface of the cylindrical section 54 and housed in a groove between the cylindrical section 54 and the cylindrical section 55.

A current source 65 is connected to each of the coils contained in the one or more electromagnets 45. The controller 2 controls the current source 65 to start and stop supplying the current to each of the coils contained in the one or more electromagnets 45, and further controls the direction of the current and the value of the current. Note that when the plasma processing apparatus 1 includes the multiple electromagnets 45, the coils of the multiple electromagnets 45 may be connected to a single current source, or may be separately connected to different current sources.

The one or more electromagnets 45 form a magnetic field axially symmetrical with respect to the center axis Z in the chamber 10. Controlling the current supplied to each of the one or more electromagnets 45 allows adjustment of the magnetic field intensity distribution (or magnetic flux density) in the radial direction from the center axis Z. The plasma processing apparatus 1 can thus adjust the radial distribution of the density of the plasma generated in the chamber 10.

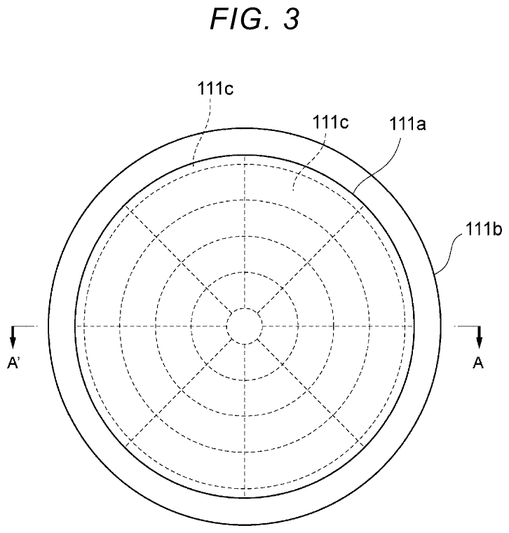

FIG. 3 is a diagram showing an example of the upper surface of the substrate support 11. The substrate support 11 has the central region 111a, which supports the substrate W, and the annular region 111b, which supports the ring assembly 112, as shown in FIG. 3. The central region 111a has multiple zones 111c, as indicated by the broken lines in FIG. 3. In the present embodiment, the temperature controlling module can control the temperature of the substrate W or the substrate support 11 for each of the zones 111c. The number of the zones 111c and the area and shape of each of the zones 111c may be set as appropriate in accordance with conditions required to control the temperature of the substrate W.

FIG. 4 shows an example of a cross section of the substrate support 11. FIG. 4 shows a portion of the cross section of the substrate support 11 taken along the line AA′ in FIG. 3. The substrate support 11 includes the electrostatic chuck 1111, the base 1110, and a control substrate 80, as shown in FIG. 4. The electrostatic chuck 1111 has multiple heaters 200 and multiple resistors 201 disposed therein. In the present embodiment, one heater 200 and one resistor 201 are disposed in the electrostatic chuck 1111 in each of the zones 111c shown in FIG. 3. In each of the zones 111c, the resistor 201 is disposed near the heater 200. In one example, the resistor 201 may be disposed between the heater 200 and the base 1110 and closer to the heater 200 than to the base 1110. The resistors 201 are each so configured that the resistance thereof changes in accordance with the temperature. In one example, the resistors 201 may each be a thermistor (temperature sensor).

The base 1110 has one or more through holes 90, which pass through the base 1110 from the upper surface thereof (surface facing electrostatic chuck 1111) to the lower surface thereof (surface facing control substrate 80). The multiple heaters 200 and the multiple resistors 201 may be electrically connected to the control substrate 80 via the through hole 90. In the present embodiment, a connector 91 is fitted into the through hole 90 at one end thereof at the upper surface of the base 1110, and a connector 92 is fitted into the through hole 90 at one end thereof at the lower surface of the base 1110. The multiple heaters 200 and the multiple resistors 201 are electrically connected to the connector 91. The multiple heaters 200 and the multiple resistors 201 may be connected to the connector 91, for example, via wires disposed in the electrostatic chuck 1111. The connector 92 is electrically connected to the control substrate 80. In addition, multiple wires 93, which electrically connect the connector 91 and the connector 92 to each other, are disposed in the through hole 90. The multiple heaters 200 and the multiple resistors 201 can thus be electrically connected to the control substrate 80 via the through hole 90. Note that the connector 92 may function as a support member that fixes the control substrate 80 to the base 1110.

The control substrate 80 is a substrate at which elements that control the multiple heaters 200 and/or the multiple resistors 201 are disposed. The control substrate 80 can be disposed so as to face the lower surface of the base 1110 in parallel to the lower surface. The control substrate 80 may be disposed so as to be surrounded by an electrically conductive member. The control substrate 80 may be supported by the base 1110 via a support member other than the connector 92.

The control substrate 80 can be electrically connected to a power supply 70 via wiring 73. That is, the power supply 70 can be electrically connected to the multiple heaters 200 via the control substrate 80. The power supply 70 generates power to be supplied to the multiple heaters 200. The power supplied from the power supply 70 to the control substrate 80 can thus be supplied to the multiple heaters 200 via the connector 92, the wires 93, and the connector 91. Note that an RF filter that reduces RF may be disposed between the power supply 70 and the control substrate 80. The RF filter may instead be provided outside the plasma processing chamber 10.

The control substrate 80 can be communicatively connected to the controller 2 via wiring 75. The wiring 75 may be an optical fiber. In this case, the control substrate 80 communicates with the controller 2 via optical communication. The wiring 75 may instead be metal wiring.

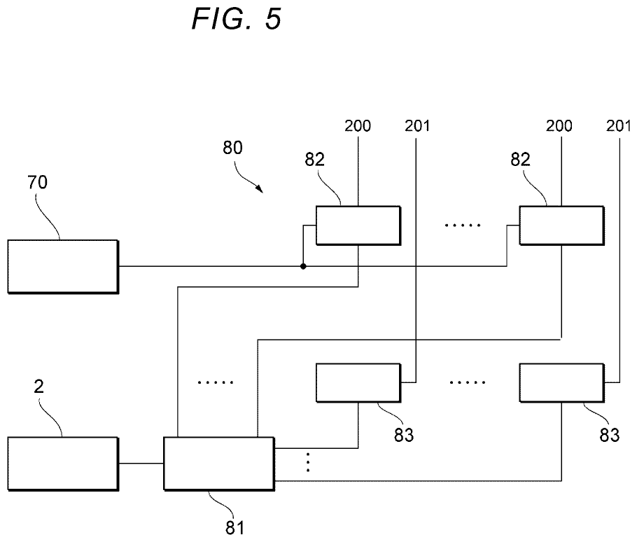

FIG. 5 is a block diagram showing an example of the configuration of the control substrate 80. A controller 81, and multiple supplies 82 and multiple measuring sections 83, which are examples of the elements, are disposed at the control substrate 80. The multiple supplies 82 and the multiple measuring sections 83 are provided in correspondence with the multiple heaters 200 and the multiple resistors 201, respectively. One supply 82 and one measuring section 83 may be provided for one heater 200 and one resistor 201.

The measuring sections 83 each generate a voltage based on the resistance of the resistor 201 provided in correspondence with the measuring section 83, and supply the generated voltage to the controller 81. The measuring sections 83 may each be configured to convert the voltage generated in accordance with the resistance of the corresponding resistor 201 into a digital signal and output the digital signal to the controller 81.

The controller 81 controls the temperature of the substrate W in each of the zones 111c. The controller 81 controls the power supplied to the multiple heaters 200 based on a set temperature received from the controller 2 and the voltages indicated by the digital signals received from the measuring sections 83. As an example, the controller 81 calculates the temperatures of the resistors 201 (hereinafter also referred to as the “measured temperatures”) based on the voltages indicated by the digital signals received from the measuring sections 83. The controller 81 then controls the supplies 82 based on the set temperature and the measured temperatures. The supplies 82 each determine whether to supply the heater 200 with the power supplied from the power supply 70 under the control of the controller 81. The supplies 82 may each increase or decrease the power supplied from the power supply 70 and supply the resultant power to the corresponding heater 200 under the control of the controller 81. The substrate W, the electrostatic chuck 1111, and/or the base 1110 can thus each be set at a predetermined temperature.

### <Example of Configuration of Substrate Processing System>

FIG. 5A is a diagram illustrating an example of a configuration of a substrate processing system. FIG. 5A schematically shows a substrate processing system (hereinafter, referred to as a “substrate processing system PS”) according to an exemplary embodiment.

A substrate processing system PS includes substrate processing chambers PM1 to PM6 (hereinafter, also collectively referred to as a “substrate processing module PM”), a transfer module TM, load lock modules LLM1 and LLM2 (hereinafter, also collectively referred to as a “load lock module LLM”), a loader module LM, and load ports LP1 to LP3 (hereinafter, also collectively referred to as a “load port LP”). A controller CT controls each component of the substrate processing system PS to execute given processing on the substrate W.

The substrate processing module PM executes processing such as etching processing, trimming processing, film formation processing, annealing processing, doping processing, lithography processing, cleaning processing, and ashing processing on the substrate W therein. At least one of the substrate processing chambers PM1 to PM6 may be the plasma processing apparatus 1 shown in FIGS. 1 and 2. At least one of the substrate processing chambers PM1 to PM6 may be a plasma processing apparatus using any plasma source such as inductively-coupled plasma or microwave plasma. At least one of the substrate processing chambers PM1 to PM6 may be a measurement module, and the film thickness of a film formed on the substrate W, the dimension of a pattern formed on the substrate W, or the like may be measured by using, for example, an optical method.

The transfer module TM includes a transfer device that transfers the substrate W, and transfers the substrate W between the substrate processing modules PM or between the substrate processing module PM and the load lock module LLM. The substrate processing module PM and the load lock modules LLM are disposed adjacent to the transfer module TM. The transfer module TM, the substrate processing module PM, and the load lock module LLM are spatially separated or connected by openable and closable gate valves.

In one or more embodiments, the transfer device included in the transfer module TM transfers the substrate W from the transfer module TM to the plasma processing space 10s of the plasma processing apparatus 1, which is an example of the substrate processing module PM. In the transfer device, the substrate W is placed on the central region 111a of the substrate support 11. The plasma processing apparatus 1 may include a lifter, and the transfer device may place the substrate W on the lifter. The lifter is configured to raise and lower the inside of a plurality of through-holes provided in the substrate support 11. When the lifter is raised, the distal end of the lifter protrudes from the central region 111a of the substrate support 11, and the substrate W is held at this position. When the lifter is lowered, the distal end of the lifter is accommodated in the substrate support 11, and the substrate W is placed on the central region 111a of the substrate support 11. As an example, the transfer device may be a handler that transfers a substrate such as a silicon wafer.

The load lock modules LLM1 and LLM2 are provided between the transfer module TM and the loader module LM. The load lock module LLM can switch a pressure therein to an atmospheric pressure or a vacuum. The “atmospheric pressure” may be a pressure outside each module included in the substrate processing system PS. Further, the “vacuum” may be a medium vacuum of, for example, 0.1 Pa to 100 Pa at a pressure lower than the atmospheric pressure. The load lock module LLM transfers the substrate W from the loader module LM which is at the atmospheric pressure to the transfer module TM which is at a vacuum, and transfers the substrate W from the transfer module TM which is at a vacuum to the loader module LM which is at the atmospheric pressure.

The loader module LM includes a transfer device that transfers the substrate W, and transfers the substrate W between the load lock module LLM and a load port LP. For example, a front opening unified pod (FOUP) in which 25 substrates W can be accommodated or an empty FOUP can be placed in the load port LP. The loader module LM takes the substrate W out from the FOUP in the load port LP and transfers the substrate W to the load lock module LLM. Further, the loader module LM takes the substrate W out from the load lock module LLM and transfers the substrate W to the FOUP in the load port LP.

The controller CT controls each component of the substrate processing system PS to execute given processing on the substrate W. The controller CT stores recipes for which process procedures, process conditions, transfer conditions, and the like are set, and controls each configuration of the substrate processing system PS to execute given processing on the substrate W in accordance with the recipes. The controller CT may also serve as a part or the entire function of the controller 2 illustrated in FIG. 1.

### <Example of Plasma Processing Method in First Embodiment>

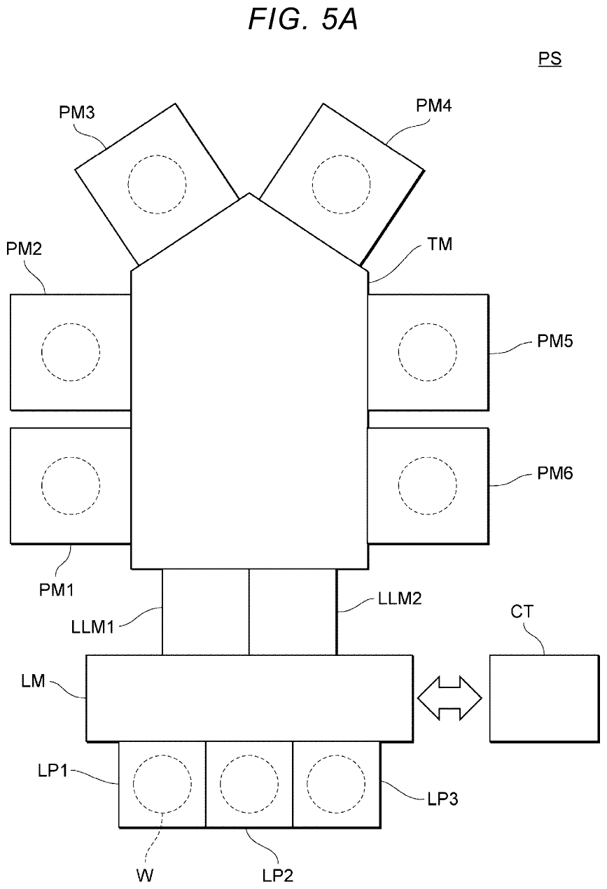

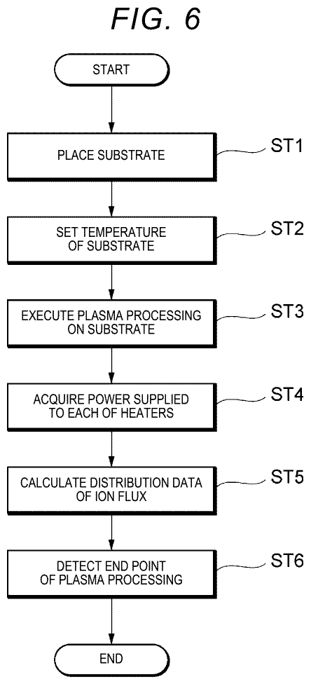

The disclosure in a first embodiment provides a technique for easily and reliably detecting the end point of plasma processing. FIG. 6 is a flowchart showing a plasma processing method (hereinafter, also referred to as a “plasma processing method”) according to one or more embodiments. As shown in FIG. 6, the plasma processing method includes a step (ST1) of placing a substrate, a step (ST2) of setting a temperature of the substrate, a step (ST3) of executing plasma processing on the substrate, a step (step ST4) of acquiring the power supplied to each of the heaters, a step (step ST5) of calculating distribution data of ion flux, and a step (ST6) of detecting an end point of the plasma processing. The process in each of the steps may be carried out by the plasma processing system shown in FIG. 1. Hereinafter, as an example, the controller 2 controls each part of the plasma processing apparatus 1 to perform the present plasma processing method.

First, in step ST1, the substrate is placed at the substrate support 11. The substrate may be a substrate in which semiconductor devices are formed. Thereafter, in step ST2, the temperature of the substrate is set. In one example, the controller 2 controls the controller 81 disposed at the control substrate 80 in such a way that the temperature of the substrate becomes the set temperature in each of the zones 111c. The controller 2 acquires the power supplied to each of the heaters 200 in the state in which the temperature of the substrate is stable at the set temperature, and stores the acquired power in the storage 2a2.

After the temperature of the substrate is stabilized at the set temperature, in step ST3, plasma is generated in the plasma processing chamber 10 to execute plasma processing on the substrate. The plasma processing may include plasma etching processing for forming a semiconductor element on a substrate.

In step ST3 of one or more embodiments, the processing gas is supplied to the shower head 13 by the gas supply 20 shown in FIG. 2, and is supplied from the shower head 13 to the plasma processing space 10s. The processing gas supplied at this point in time includes a gas that generates an active species required to etch the substrate W. Then, one or more RF signals are supplied from the RF power source 31 to the upper electrode and/or the lower electrode. The atmosphere in the plasma processing space 10s may be exhausted via the gas exhaust port 10e, and the interior of the plasma processing space 10s may be depressurized. As a result, plasma is generated in the plasma processing space 10s to execute plasma etching processing on the substrate W.

Thereafter, in step ST4, the power supplied to each of the plurality of heaters 200 is acquired. In step ST2, step ST3, and step ST4, the controller 2 controls the power supplied to each of the heaters 200 such that the temperature of the substrate in each of the zone 111c becomes the set temperature. In one or more embodiments, the controller 2 acquires power supplied to each of the plurality of heaters 200 in a state in which plasma is generated in step ST3. The power supplied to the plurality of heaters 200 may be continuously or intermittently acquired. The controller 2 may store the power supplied to each of the plurality of heaters 200 acquired in step ST4 in the storage 2a2.

Next, in step ST5, distribution data of the ion flux is calculated. The distribution data may be data on the distribution of the ion flux that occurs between the plasma generated in the plasma processing chamber 10 and the substrate.

Note that the ion flux distribution data may be calculated based on a heat flux that occurs between the substrate placed at the substrate support 11 and the plasma generated in the plasma processing chamber 10. For example, when the temperature of the substrate placed at the substrate support 11 is constant, an ion flux Γᵢ (m⁻² s⁻¹), which occurs between the substrate and the plasma generated in the plasma processing chamber 10, can be related to a heat flux Γₕₑₐₜ (W/m²), which occurs between the substrate and the plasma generated in the plasma processing chamber 10 as follows:

Γᵢ×Vdc∝Γₕₑₐₜ (1)

Here, Vdc(V) is the bias voltage (V) generated between the substrate and the plasma. The heat flux Γₕₑₐₜ, which occurs between the substrate placed at the substrate support 11 and the plasma generated in the plasma processing chamber 10, may be calculated based on the supplied power acquired in step ST4. In one example, the heat flux Γₕₑₐₜ in each of the zones 111c may be calculated based on the expression below.

Γₕₑₐₜ=(P₀−Pₕₜᵣ)/A (2)

In Expression (2), P₀ represents the power (W) supplied to the heater 200 in the zone 111c in a state in which no plasma has been generated. That is, P₀ is the power supplied to the heater 200 in the zone 111c, which is acquired in the step ST12. In Expression (2), Pₕₜᵣ represents the power (W) supplied to the heater 200 in the zone 111c in the state in which the plasma has been generated. That is, Pₕₜᵣ is the power supplied to the heater 200 in the zone 111c, which is acquired in step ST4. As an example, Pₕₜᵣ may be the power (W) supplied to the heater 200 in the zone 111c when the power (W) becomes substantially constant after the plasma is generated. In Expression (2), A represents the area (m²) of the zone 111c. The controller 2 may store the distribution data of the ion flux calculated in step ST5 in the storage 2a2. In one or more embodiments, the distribution data of the ion flux may be continuously or intermittently calculated during the plasma processing.

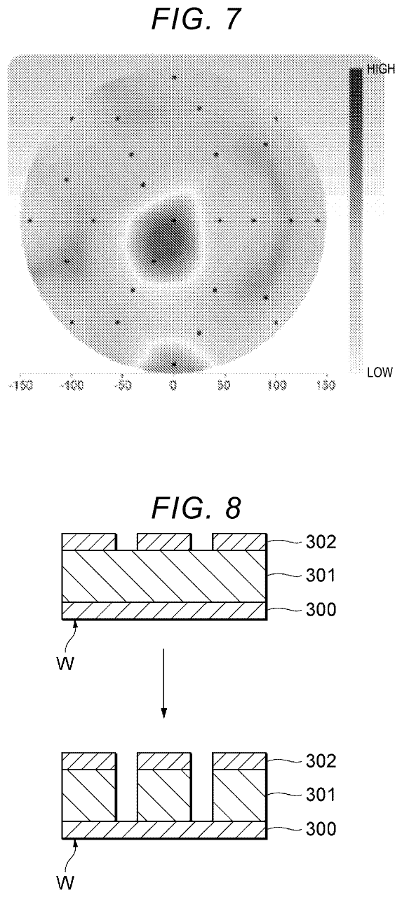

FIG. 7 is a diagram showing an example of distribution data of the ion flux. The distribution data of the ion flux may be visualized by showing the strength of the ion flux in different colors or in different shadings. The distribution data includes not only the distribution itself of the ion flux as shown in FIG. 7, but also various numerical information corresponding to the distribution. FIG. 7 shows, as an example, distribution data calculated for a substrate having the diameter of 300 mm.

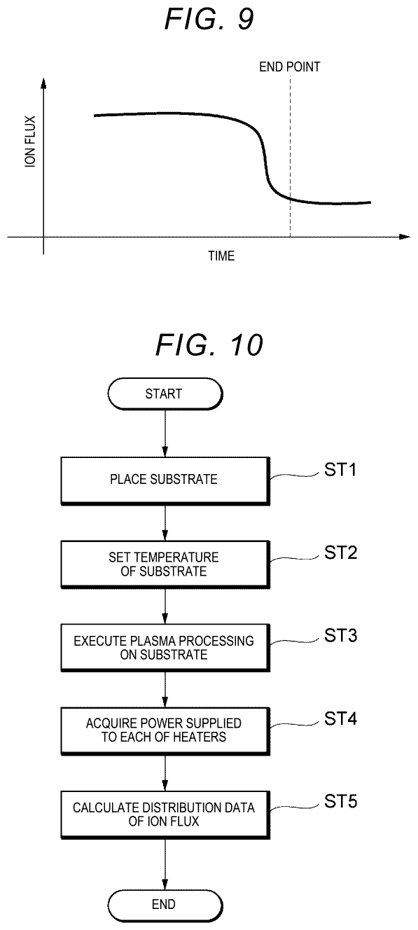

In step ST6, the end point of the plasma processing is then detected based on the distribution data of the ion flux. FIG. 8 shows an example of plasma processing for etching a silicon-containing film (to-be-etched film) 301 formed on an underlying film 300 of the substrate W. In one or more embodiments, a mask film 302 formed in a predetermined pattern is formed on the silicon-containing film 301. In one or more embodiments, the plasma processing is executed by using a processing gas having a sufficient selectivity between the silicon-containing film 301 and the underlying film 300. In one or more embodiments, when the silicon-containing film 301 is etched, the ion flux generated between the plasma and the substrate is reduced. As shown in FIG. 9, the end point of the plasma processing (etching processing) of the silicon-containing film 301 is detected by monitoring the temporal change of the distribution data of the ion flux and detecting that the value of the distribution data of the ion flux has fallen below a predetermined threshold value. The end point of the plasma processing may be detected by the fact that the value of the distribution data of the ion flux falls below a threshold value on the entire surface of the substrate, or may be detected by the fact that the value of the distribution data of the ion flux falls below a threshold value in a part of the substrate surface. The end point of the plasma processing may include a case in which detection is performed based on the fact that the value of the ion flux in the central region of the substrate falls below a threshold value, or a case in which detection is performed based on the fact that the value of the ion flux in the outer peripheral region of the substrate falls below a threshold value.

The controller 2 may stop the supply of the processing gas and the supply of the RF source signal in the chamber 10 based on the detection of the end point of the plasma processing. In the substrate processing, subsequent to step ST6, the next plasma processing may be performed, and in this case as well, the end point of the plasma processing may be detected, similarly to step ST6. That is, the end point may be detected in each of a plurality of consecutive plasma processing, for example, in each plasma processing of different laminated films, or may be detected in some plasma processing. The plasma processing may include etching of a silicon-containing film, etching of an organic film, etching of a metal film or a metal-containing film, cleaning of by-products that adhere to the inside of the processing chamber, ashing of the organic film, or the like.

According to one or more embodiments of the present disclosure, the plasma processing method includes (a) placing a substrate on the substrate support 11, (b) generating plasma in the chamber 10 to execute plasma processing on the substrate on the substrate support 11, (c) acquiring distribution data that is data related to the distribution of the ion flux generated between the plasma generated in the chamber 10 and the substrate placed on the substrate support 11 in the (b), and (d) detecting an end point of the plasma processing based on the distribution data. According to the present exemplary embodiment, distribution data of the ion flux may be acquired, and the end point of the plasma processing may be detected based on the distribution data. Accordingly, in order to detect the end point of the plasma processing, it is not necessary to prepare an optical apparatus or provide a detection window in the chamber, and the end point of the plasma processing can be easily and reliably detected. When a reaction product or the like is deposited on the detection window, maintenance such as cleaning of the detection window may be performed, but according to the present exemplary embodiment, such maintenance is not required, and the throughput of the apparatus may be improved.

### <Example of Plasma Processing Method in Second Embodiment>

The disclosure in a second embodiment provides a technique for grasping the state in the chamber during the transitional period of plasma. FIG. 10 is a flowchart showing a plasma processing method (hereinafter, also referred to as the present plasma processing method) according to one or more embodiments. As shown in FIG. 10, the present plasma processing method includes a step (ST1) of placing a substrate, a step (ST2) of setting a temperature of the substrate, a step (ST3) of executing plasma processing on the substrate, a step (step ST4) of acquiring the power supplied to each of the heaters, and a step (step ST5) of calculating distribution data of ion flux. The process in each of the steps may be carried out by the plasma processing system shown in FIG. 1. Hereinafter, as an example, the controller 2 controls each part of the plasma processing apparatus 1 to perform the present plasma processing method.

First, in step ST1, the substrate is placed at the substrate support 11. The substrate may be a substrate in which semiconductor devices are formed. Thereafter, in step ST2, the temperature of the substrate is set. In one example, the controller 2 controls the controller 81 disposed at the control substrate 80 in such a way that the temperature of the substrate becomes the set temperature in each of the zones 111c. The controller 2 acquires the power supplied to each of the heaters 200 in the state in which the temperature of the substrate is stable at the set temperature, and stores the acquired power in the storage 2a2.

After the temperature of the substrate is stabilized at the set temperature, in step ST3, plasma is generated in the plasma processing chamber 10 to execute plasma processing on the substrate. The plasma processing may include plasma etching processing for forming a semiconductor element on a substrate.

In step ST3 of one or more embodiments, the processing gas is supplied to the shower head 13 by the gas supply 20 shown in FIG. 2, and is supplied from the shower head 13 to the plasma processing space 10s. The processing gas supplied at this point in time includes a gas that generates an active species required to etch the substrate W. Then, one or more RF signals are supplied from the RF power source 31 to the upper electrode and/or the lower electrode. The atmosphere in the plasma processing space 10s may be exhausted via the gas exhaust port 10e, and the interior of the plasma processing space 10s may be depressurized. As a result, plasma is generated in the plasma processing space 10s to execute plasma etching processing on the substrate W.

Thereafter, in step ST4, the power supplied to each of the plurality of heaters 200 is acquired. In step ST3 and step ST4, the controller 2 controls the power supplied to each of the heaters 200 in such a way that the temperature of the substrate becomes the set temperature in each of the zones 111c. In one or more embodiments, in step ST4, the controller 2 acquires the power supplied to each of the plurality of heaters 200 in a state in which plasma is generated immediately before the plasma is generated. The power supplied to the plurality of heaters 200 may be continuously or intermittently acquired. The controller 2 may store the power supplied to each of the plurality of heaters 200 acquired in step ST4 in the storage 2a2.

Next, in step ST5, distribution data of the ion flux is calculated. The distribution data may be data on the distribution of the ion flux that occurs between the plasma generated in the plasma processing chamber 10 and the substrate.

Note that the ion flux distribution data may be calculated based on a heat flux that occurs between the substrate placed at the substrate support 11 and the plasma generated in the plasma processing chamber 10. For example, when the temperature of the substrate placed at the substrate support 11 is constant, an ion flux Ti (m⁻² s⁻¹), which occurs between the substrate and the plasma generated in the plasma processing chamber 10, can be related to a heat flux Γₕₑₐₜ (W/m²), which occurs between the substrate and the plasma generated in the plasma processing chamber 10 as follows:

Γᵢ×Vdc∝Γₕₑₐₜ (1)

Here, Vdc(V) is the bias voltage (V) generated between the substrate and the plasma. The heat flux Γₕₑₐₜ, which occurs between the substrate placed at the substrate support 11 and the plasma generated in the plasma processing chamber 10, may be calculated based on the supplied power acquired in step ST14. In one example, the heat flux Γₕₑₐₜ in each of the zones 111c may be calculated based on the expression below.

Γₕₑₐₜ=(P₀−Pₕₜᵣ)/A (2)

In Expression (2), P₀ represents the power (W) supplied to the heater 200 in the zone 111c in a state in which no plasma has been generated. That is, P₀ is the power supplied to the heater 200 in the zone 111c, which is acquired in the step ST12. In Expression (2), Pₕₜᵣ represents the power (W) supplied to the heater 200 in the zone 111c in the state in which the plasma has been generated. That is, Pₕₜᵣ is the power supplied to the heater 200 in the zone 111c, which is acquired in the step ST14. In Expression (2), A represents the area (m²) of the zone 111c. The controller 2 may store the distribution data of the ion flux calculated in step ST5 in the storage 2a2. In one or more embodiments, the distribution data of the ion flux may be continuously or intermittently calculated during plasma generation.

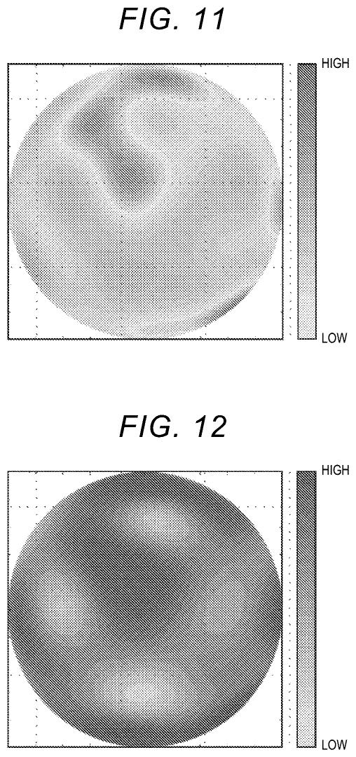

FIG. 11 is a diagram showing an example of distribution data of the ion flux. The distribution data of the ion flux may reflect the state of the plasma formed on the substrate during the transitional period. The distribution data of the ion flux may be visualized by showing the strength of the ion flux in different colors or in different shadings. The distribution data of the ion flux may be distribution data during a transitional period in which the state of the plasma changes. The plasma transitional period may include the start of plasma generation (at ignition), the switching between the steps of plasma processing, the end of plasma generation (at extinguishing), and the like. The transitional period of the plasma at the start of the plasma generation may include a timing when the state of the plasma changes, that is, a timing from the moment when the plasma is generated to when the generated plasma is stabilized. The start of the generation of plasma is brought about by both the supply of the processing gas and the supply of the RF source signal in the plasma processing chamber 10. The supply of the processing gas and the supply of the RF source signal may be performed at the same time, or either of the supply of the processing gas or the supply of the RF source signal may be performed first. The switching between the steps of plasma processing may include, for example, switching between a first step in which a first processing gas is supplied to the chamber 10 and a second step in which a second processing gas is supplied, switching between a first step in which a first signal is supplied to at least one of the lower electrode or the upper electrode and a second step in which a second signal is supplied, switching between a first step in which the pressure in the chamber 10 is adjusted to a first pressure and a second step in which the pressure in the chamber 10 is adjusted to a second pressure, or the like. Further, switching between the steps of plasma processing also includes switching at least one of the processing gases supplied to the chamber 10, the signals supplied to the lower electrode or the upper electrode, and the pressures within the chamber 10.

FIG. 11 is an example of distribution data of a state at the start of plasma generation. In the example shown in FIG. 11, the ion flux is higher in the outer edge region at the upper portion and the outer edge region at the lower right portion than in other regions in FIG. 11, and the distribution of the ion flux on the substrate at the start of plasma generation can be grasped.

In step ST5, the temporal change of the distribution data of the ion flux may be calculated. FIG. 12 shows an example of distribution data after the start of plasma generation (after a predetermined time elapses from the start of plasma generation). The changes over time in the distribution of the ion flux at the start of plasma generation can be grasped from the distribution data as shown in FIGS. 11 and 12. The distribution data may be continuously or intermittently calculated.

According to one or more embodiments of the present disclosure, the plasma processing method includes (a) placing a substrate on the substrate support 11, (b) generating plasma in the chamber 10 to execute plasma processing on the substrate placed on the substrate support 11, and (c) acquiring distribution data that is data related to the distribution of the ion flux generated between the plasma and the substrate placed on the substrate support 11 during a transitional period in which the state of the plasma generated in the chamber 10 changes. According to the present exemplary embodiment, by acquiring the distribution data of ion flux during a transitional period of the state of plasma, it is possible to grasp the state of the plasma on the substrate during the transitional period. As a result, it is possible to detect an error caused by, for example, the generation of particles, which may occur during the transitional period of plasma. Further, the location of the error on the substrate can also be grasped.

In the present plasma processing method, since the temporal change of distribution data is acquired in the (c), the state of the plasma inside the chamber 10 during a transitional period can be accurately grasped.

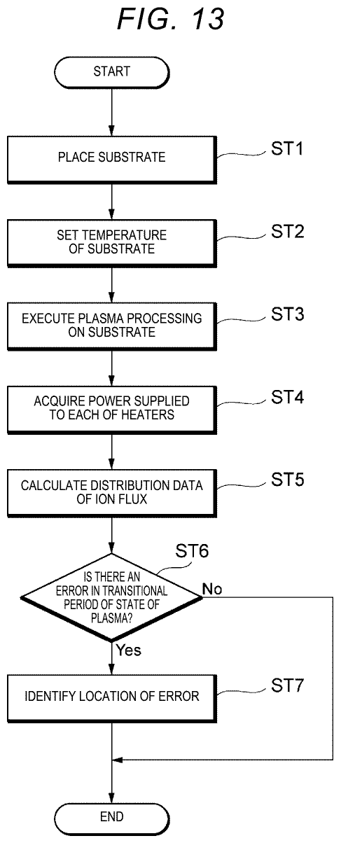

FIG. 13 is a flowchart showing the present plasma processing method according to one or more embodiments. As shown in FIG. 13, the present plasma processing method may include, in addition to step ST1 to step ST5, a step (ST6) of determining whether there is an error in the state of the plasma during the transitional period based on the distribution data. The present plasma processing method may further include a step (ST7) of identifying a location where an error is found in the state of the plasma during the transitional period, based on the distribution data.

In step ST6, a threshold value of an error is set in the distribution data, the distribution data is compared with the threshold value, and when the distribution data is equal to or lower than the threshold value (step ST6: No), it is determined that there is no error in the state of the plasma during the transitional period. When the distribution data exceeds the threshold value (step ST6: Yes), it is determined that there is an error in the state of the plasma during the transitional period. In this case, the controller 2 may stop the plasma processing. In step ST7, the portion exceeding the threshold value, that is, the location where an error is found in the state of the plasma during the transitional period on the substrate, is identified from the distribution data. The positional information of the location where an error is found may be stored in the storage 2a2.

### <Example of Plasma Processing Method in Third Embodiment>

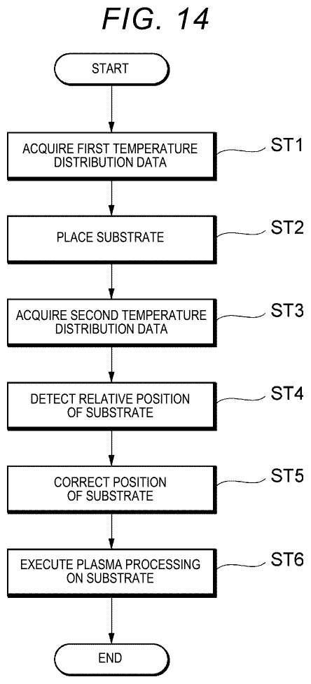

The disclosure in a third embodiment provides a technique for detecting mis-alignment of a substrate. FIG. 14 is a flowchart showing a plasma processing method according to one or more embodiments (hereinafter, also referred to as “the present method”). The present method is an example of a substrate processing method. As shown in FIG. 14, the present method includes a step of acquiring first temperature distribution data (step ST1), a step of placing a substrate (step ST2), a step of acquiring second temperature distribution data (step ST3), and a step of detecting the relative position of the substrate (step ST4). The present method may further include a step of correcting the position of the substrate (step ST5) and/or a step of executing plasma processing on the substrate (step ST6). The processing in each step of the present method may be executed by the plasma processing apparatus 1 and/or the substrate processing system PS operating mainly under the control of the controller 2 and/or the controller CT. Hereinafter, as an example, a case will be mainly described in which the controller 2 controls each part of the plasma processing apparatus 1 to execute the present method.

### (Step ST1: Acquiring First Temperature Distribution Data)

In step ST1, first temperature distribution data is acquired. The first temperature distribution data is data that includes the temperature distribution of the central region 111a of the substrate support 11 in a state in which the substrate W is not placed (hereinafter, also referred to as a “first temperature distribution”).

First, the temperature of the substrate support 11 is adjusted to the set temperature. In an example, the controller 2 controls the controller 81 disposed on the control substrate 80 such that the temperature of the substrate support 11 becomes the set temperature in each of the zones 111c.

Next, the measurement temperature of the resistor 201 in each of the zones 111c is calculated in a state in which the temperature of the substrate support 11 is stabilized at the set temperature. In one or more embodiments, the measurement temperature may be calculated immediately before the substrate W is placed on the substrate support 11. The controller 2 calculates the temperature distribution (first temperature distribution) of the central region 111a of the substrate support 11 based on the measurement temperature of the resistor 201 in each of the zones 111c, and stores the temperature distribution as first temperature distribution data in the storage 2a2.

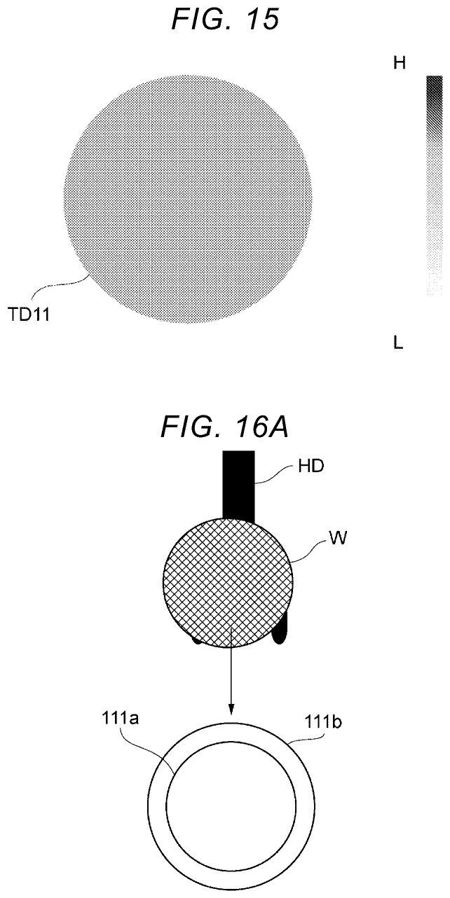

FIG. 15 is a schematic diagram showing an example of the first temperature distribution. In FIG. 15, “H” indicates that the temperature is higher than that of “L”. In this example, first temperature distribution TD11 is uniform across each zone 111c of the central region 111a of the substrate support 11.

### (Step ST2: Placing Substrate)

In step ST2, the substrate W is placed on the substrate support 11. The substrate W is transferred into the chamber 10 by the transfer device and placed in the central region 111a of the substrate support 11. When the substrate support 11 includes a lifter, the transfer device may place the substrate W on the lifter. That is, the substrate W may be delivered from the transfer device to the lifter, and the substrate W may be placed on the substrate support 11 as the lifter is lowered. Next, a DC voltage is supplied to the electrostatic chuck 1111, and the substrate W is attracted and held in the substrate support 11. In one or more embodiments, the transfer device may be a transfer device included in the transfer module TM shown in FIG. 5A. The transfer device may be a handler HD configured to support the substrate W on the back surface of the substrate W. The substrate W may be supported by the handler HD after being aligned with respect to a reference position of the handler HD.

FIG. 16A is a schematic diagram showing an example of the substrate W during the processing in step ST2. FIG. 16A is an example of a state in which the substrate W is supported by the handler HD. FIG. 16B is a schematic diagram showing an example of the substrate W after the processing in step ST2 is performed. FIG. 16B is an example of a state in which the substrate W shown in FIG. 16A is placed in the central region 111a of the substrate support 11.

The substrate W is aligned in advance with respect to the reference position of the handler HD at the central position thereof. However, due to the delivery of the substrate W in the transfer path to the chamber 10, the vibration of the handler HD, or the like, the position of the substrate W on the handler HD may be mis-aligned. That is, as shown in FIG. 16A, the substrate W on the handler HD may be mis-aligned. When the substrate W is placed from the handler HD to the substrate support 11 in this state, mis-alignment of the substrate W on the substrate support 11 may occur as shown in FIG. 16B. In FIG. 16B, the substrate W is placed at a position biased in the central region 111a of the substrate support 11, and a center C of the substrate W is mis-aligned from the reference position (for example, a center O of the central region 111a) of the substrate support 11.

### (Step ST3: Acquiring Second Temperature Distribution Data)

In step ST3, second temperature distribution data is acquired. The second temperature distribution data is data that includes the temperature distribution (hereinafter, also referred to as a “second temperature distribution”) of the central region 111a of the substrate support 11 in a state in which the substrate W is placed.

The measurement temperature of the resistor 201 in each of the zones 111c is calculated in a state in which the substrate W is placed on the substrate support 11. The controller 2 calculates the temperature distribution (second temperature distribution) of the central region 111a of the substrate support 11 based on the measurement temperature of the resistor 201 in each of the zones 111c, and stores the temperature distribution as second temperature distribution data in the storage 2a2. In one or more embodiments, the measurement temperature may be calculated immediately after the substrate W is placed on the substrate support 11. It is considered that the temperature of the zone 111c where the substrate W is placed temporarily rises or falls due to a temperature difference with the substrate W immediately after the substrate W is placed, and returns to the set temperature after a predetermined period elapses. By calculating the measurement temperature immediately after the substrate W is placed, the temperature region of the location where the substrate W is placed may appear different from the temperature regions of the other locations in the second temperature distribution data.

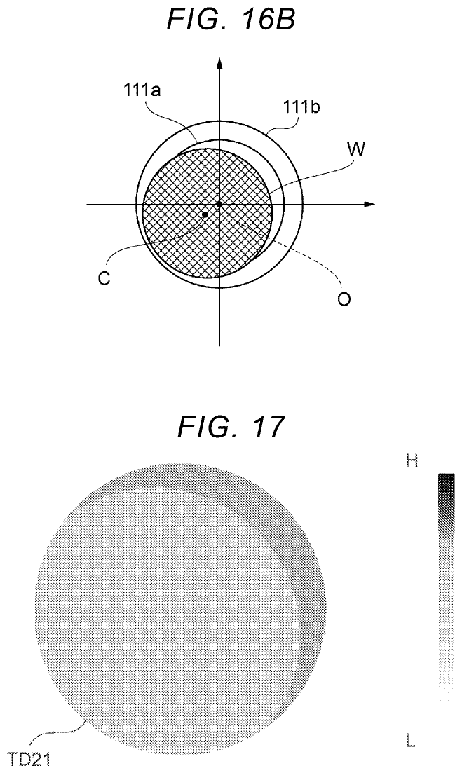

FIG. 17 is a schematic diagram showing an example of the second temperature distribution. FIG. 17 is an example of the second temperature distribution in the state shown in FIG. 16B. In FIG. 17, “H” indicates that the temperature is higher than that of “L”. In FIG. 17, temperature of the region where the substrate W is placed is lower than that of the other locations (this example is the case in which the temperature of the substrate W to be transferred is lower than the set temperature of the substrate support 11). That is, in a second temperature distribution TD21, a region where the temperature is low appears corresponding to the mis-alignment of the substrate W (FIG. 16B).

### (Step ST4: Detecting Relative Position of Substrate)

In step ST4, the relative position of the substrate W with respect to the substrate support 11 is detected based on the first temperature distribution data and the second temperature distribution data. First, the controller 2 compares the first temperature distribution data stored in the storage 2a2 with the second temperature distribution data. Based on the comparison results, the controller 2 estimates that the portion where a temperature change has occurred or where the temperature change is equal to or greater than a given temperature is the location where the substrate W is placed, thereby detecting the position of a part (or the whole) of the outer edge WE of the substrate W.

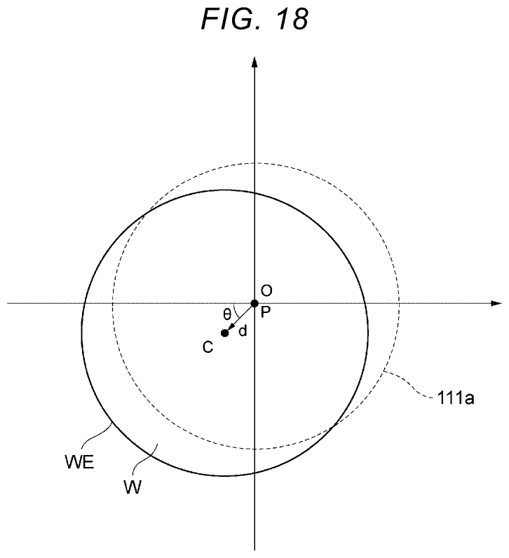

FIG. 18 is a diagram showing an example of a method of detecting the relative position of a substrate. The controller 2 calculates the position of the center C of a wafer W from a part (or the whole) of the outer edge WE of the wafer W that has been detected. Accordingly, the relative position of the center C of the substrate W to the center (reference position O) of the central region 111a of the substrate support 11 is detected. In an example, the relative position may include a mis-alignment amount “d” and a mis-alignment angle “θ” between the central position C of the wafer W and the reference position O. The mis-alignment angle “θ” may be, for example, an angle with respect to a reference line extending from the reference position O in a predetermined direction. The controller 2 stores the detected relative position in the storage 2a2.

### (Step ST5: Correcting Position of Substrate)

In step ST5, the position of the substrate W is corrected.

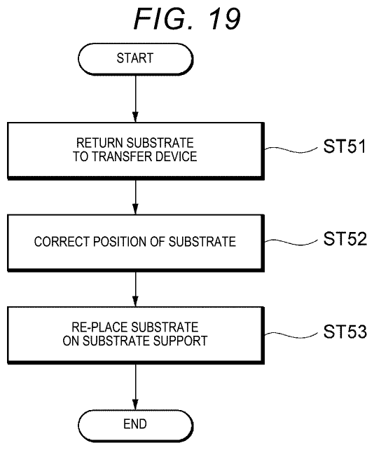

FIG. 19 is a flowchart showing an example of step ST5. As shown in FIG. 19, step ST5 may include a step of returning the substrate to the transfer device (step ST51), a step of correcting the position of the substrate (step ST52), and a step of re-placing the substrate on the substrate support (step ST53).

In step ST51, the substrate W is returned to the transfer device. First, the attraction of the substrate W by the electrostatic chuck 1111 is released. Next, the substrate W is taken out from the substrate support 11 by the transfer device. In one or more embodiments, the substrate W may be delivered to the transfer device through the lifter.

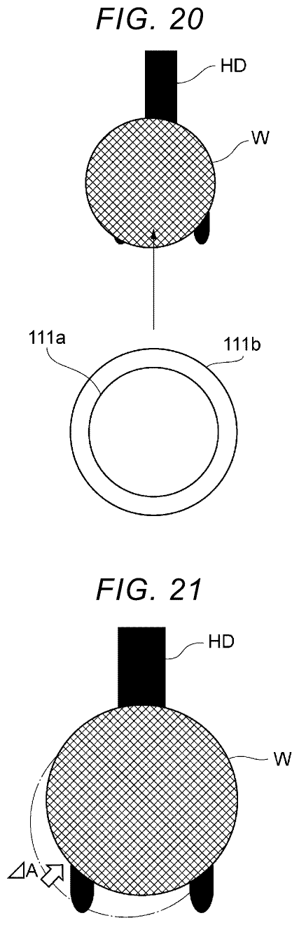

FIG. 20 is a schematic diagram showing an example of the substrate W after the processing in step ST51 is performed. FIG. 20 is an example of a state in which the substrate W shown in FIG. 16B is returned to the handler HD. In this state, the substrate W on the handler HD is still mis-aligned.

In step ST52, the position of the substrate W on the transfer device is corrected. The controller 2 calculates a correction amount AA based on the relative position of substrate W with respect to the substrate support 11 stored in the storage 2a2. The correction amount AA may be an amount of movement of the substrate W and/or the transfer device necessary for resolving the mis-alignment of the substrate W on the transfer device. Based on the correction amount AA, the substrate W is placed at a normal position on the transfer device (a position predetermined with respect to a reference position of the transfer device).

FIG. 21 is a schematic diagram showing an example of the substrate W after the processing in step ST52 is performed. FIG. 21 is an example of a state in which position correction has been performed with respect to the substrate W shown in FIG. 20. As shown in FIG. 21, the substrate W is moved on the handler HD by AA and placed at a normal position on the handler HD (a position predetermined with respect to the reference position of the handler HD).

In step ST53, the substrate W is re-placed in the central region 111a of the substrate support 11. Step ST53 may be executed in the same manner as step ST2.

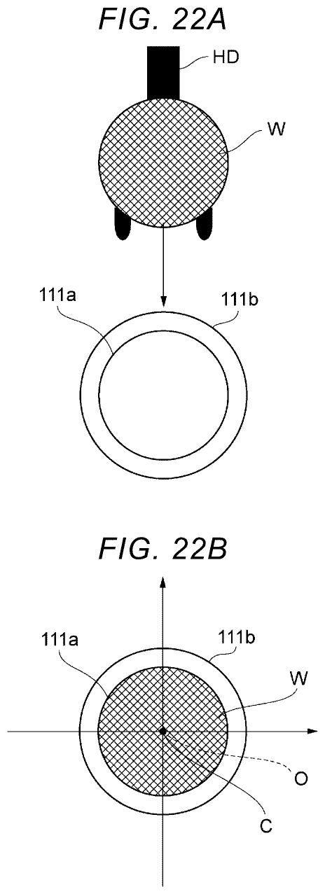

FIG. 22A is a schematic diagram showing an example of the substrate W during the processing in step ST53. FIG. 22A is an example of a state in which the substrate W is supported by the handler HD. FIG. 22B is a schematic diagram showing an example of the substrate W after the processing in step ST53 is performed. FIG. 22B is an example of a state in which the substrate W shown in FIG. 22A is placed in the central region 111a of the substrate support 11.

As shown in FIG. 22A, the substrate W is placed at a normal position on the handler HD. As a result, as shown in FIG. 22B, the re-placed substrate W is placed in the central region 111a of the substrate support 11 without mis-alignment (that is, in a state in which the center C of the substrate W coincides with the reference position O of the substrate support 11).

During the execution of step ST5, the controller 2 may control the controller 81 disposed on the control substrate 80 such that the temperature of the substrate support 11 reaches the set temperature in each of the zones 111c. In this case, during the execution of step ST51 and step ST52, the temperature distribution of the central region 111a of the substrate support 11 becomes uniform across the respective zones 111c, similarly to the first temperature distribution TD11.

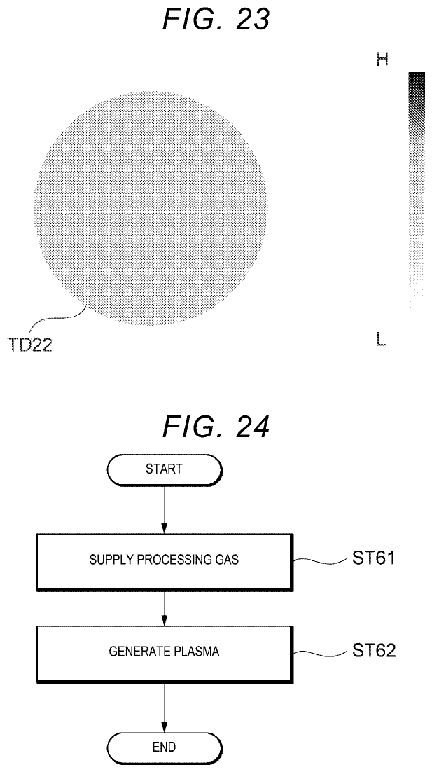

FIG. 23 is a schematic diagram showing an example of the temperature distribution in the central region 111a immediately after the substrate W is re-placed in step ST53. As shown in FIG. 23, a temperature distribution TD22 acquired immediately after the substrate W is re-placed on the substrate support 11 differs from the second temperature distribution TD21 in that a region having a low temperature appears concentrically from the center of the central region 111a of the substrate support 11.

In step ST5, the position of the substrate W may be corrected by various methods. For example, step ST53 may be executed without executing step ST52 by taking out the substrate W while shifting the position of the handler HD with respect to the substrate support 11 by AA in step ST51. Accordingly, the position of the substrate W is corrected. Further, for example, after step ST51, step ST53 may be performed without performing step ST52. Then, in step ST53, the handler HD may be moved by AA with respect to the substrate support 11 to place the substrate W on the substrate support 11. Accordingly, the position of the substrate W is corrected. Further, the position of the substrate W may be corrected on the substrate support 11. For example, the position of the substrate W may be corrected by moving the substrate W on the substrate support 11 by AA by changing the protruding height of the lifter and/or tilting the substrate support 11.

### (Step ST6: Plasma Processing of Substrate)

In step ST6, plasma processing is executed on the substrate W. In one or more embodiments, the plasma processing includes etching processing for etching a film on the substrate W by using plasma.

FIG. 24 is a flowchart showing an example of step ST6. Step ST6 may include a step of supplying a processing gas (step ST61) and a step of generating plasma (step ST62).

In step ST61, the processing gas is supplied from the gas supply 20 to the shower head 13 and supplied from the shower head 13 to the plasma processing space 10s. The processing gas supplied at this point in time includes a gas that generates an active species required to etch the substrate W.

In step ST62, the source RF signal is supplied from the RF power source 31 to the upper electrode and/or the lower electrode. The atmosphere in the plasma processing space 10s may be exhausted via the gas exhaust port 10e, and the interior of the plasma processing space 10s may be depressurized. As a result, plasma is generated in the plasma processing space 10s, and the substrate W is etched. In step ST62, a bias signal may be supplied to the lower electrode.

In step ST62, power may be supplied to each of the plurality of heaters 200 such that the temperature of each of the plurality of heaters 200 (the temperature detected by the resistor 201) reaches a constant set temperature. Accordingly, the substrate support 11 is controlled to the set temperature.

According to the present method, since the relative position of the substrate W with respect to the substrate support 11 is detected in a state in which the substrate W is placed on the substrate support 11, the detection accuracy of mis-alignment may be improved. Further, according to the present method, since the position of the substrate W is corrected based on the detected relative position, mis-alignment of the substrate W on the substrate support 11 can be suppressed. Further, according to the present method, since plasma processing is executed on the substrate W after the position of the substrate W is corrected, it is possible to avoid the defect of the plasma processing caused by the mis-alignment.

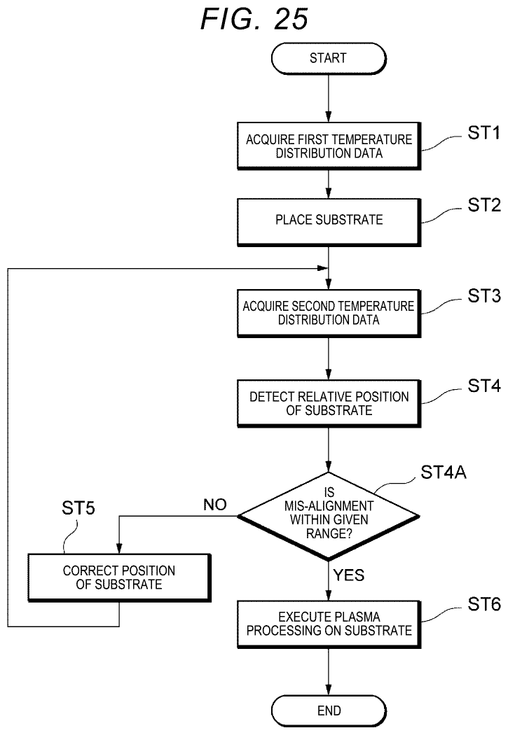

FIG. 25 is a flowchart showing another example of the present method. As shown in FIG. 25, after step ST4, the present method may further include a step ST4A of determining whether the mis-alignment detected in step ST4 is within a given range. In the present example, when it is determined in step ST4A that the mis-alignment is within the given range, step ST6 is executed without executing step ST5. Further, in the present example, step ST5, step ST3, step ST4, and step ST4A are repeated until it is determined in step ST4A that the mis-alignment is within the given range.

The embodiments of the present disclosure further include the following aspects.

### APPENDIX 1

A plasma processing method for generating plasma in a chamber to execute plasma processing on a substrate in a plasma processing apparatus having the chamber and a substrate support disposed in the chamber, the method including:
(a) placing the substrate on the substrate support;
(b) generating plasma in the chamber to execute the plasma processing on the substrate on the substrate support;
(c) acquiring data related to ion flux generated between the plasma generated in the chamber and the substrate placed on the substrate support in the (b); and
(d) detecting an end point of the plasma processing based on the data.

### APPENDIX 2

The plasma processing method according to Appendix 1, in which the data related to the ion flux is data related to distribution of the ion flux.

### APPENDIX 3

The plasma processing method according to Appendix 1 or 2, in which
the plasma processing includes etching processing for etching a film formed on the substrate, and
an end point of the etching processing is detected in the (d).

### APPENDIX 4

The plasma processing method according to any one of Appendices 1 to 3, in which the (c) includes
(c-1) supplying power to each of a plurality of heaters disposed in the substrate support,
(c-2) acquiring the power supplied to each of the plurality of heaters in a state in which the plasma is generated in the chamber, and
(c-3) calculating the data based on the power acquired for each of the plurality of heaters in the (c-2).

### APPENDIX 5

The plasma processing method according to Appendix 4, in which
the substrate support has a substrate support surface configured to support the substrate,
the substrate support surface has a plurality of support regions, and
the plurality of heaters are disposed in the substrate support in the respective support regions.

### APPENDIX 6

A plasma processing apparatus including a chamber, a substrate support disposed in the chamber, and a controller configured to execute processing for
(a) placing a substrate on the substrate support,
(b) generating plasma in the chamber to execute plasma processing on the substrate on the substrate support,
(c) acquiring data related to ion flux generated between the plasma generated in the chamber and the substrate placed on the substrate support in the (b), and
(d) detecting an end point of the plasma processing based on the data.

### APPENDIX 7

A plasma processing method for generating plasma in a chamber to execute plasma processing on a substrate in a plasma processing apparatus having the chamber and a substrate support disposed in the chamber, the method including:
(a) placing the substrate on the substrate support;
(b) generating plasma in the chamber to execute the plasma processing on the substrate on the substrate support; and
(c) acquiring distribution data that is data related to distribution of ion flux generated between the plasma and the substrate placed on the substrate support during a transitional period in which a state of the plasma generated in the chamber changes.

### APPENDIX 8

The plasma processing method according to Appendix 7, further including:
(d) determining whether there is an error in the state of the plasma during the transitional period based on the distribution data.

### APPENDIX 9

The plasma processing method according to Appendix 8, in which
in the (d), a location where the error is found in the state of the plasma during the transitional period is identified based on the distribution data.

### APPENDIX 10

The plasma processing method according to any one of Appendices 7 to 9, in which
in the (c), a temporal change of the distribution data is acquired.

### APPENDIX 11

The plasma processing method according to any one of Appendices 7 to 10, in which
the transitional period includes at least one of start of plasma generation and switching between the steps of plasma processing.

### APPENDIX 12

The plasma processing method according to any one of Appendices 7 to 11, in which
the (c) includes
   (c-1) supplying power to each of a plurality of heaters disposed in the substrate support,
   (c-2) acquiring the power supplied to each of the plurality of heaters in a state in which the plasma is generated in the chamber, and
   (c-3) calculating the distribution data based on the power acquired for each of the plurality of heaters in the (c-2).

### APPENDIX 13

The plasma processing method according to Appendix 12, in which
the substrate support has a substrate support surface configured to support the substrate,
the substrate support surface has a plurality of support regions, and
the plurality of heaters are disposed in the substrate support in the respective support regions.

### APPENDIX 14

A plasma processing apparatus including a chamber, a substrate support disposed in the chamber, and a controller configured to execute processing for
(a) placing a substrate on the substrate support,
(b) generating plasma in the chamber to execute plasma processing on the substrate on the substrate support, and
(c) acquiring distribution data that is data related to a distribution of ion flux generated between the plasma and the substrate placed on the substrate support during a transitional period in which a state of the plasma generated in the chamber changes.

### APPENDIX 15

A substrate processing method executed in a substrate processing apparatus including a chamber and a substrate support disposed in the chamber, the method including:
(a) acquiring first temperature distribution data that includes a temperature distribution of the substrate support in a state in which a substrate is not placed;
(b) placing the substrate on the substrate support;
(c) acquiring second temperature distribution data that includes a temperature distribution of the substrate support in a state in which the substrate is placed; and
(d) detecting a relative position of the substrate to the substrate support based on the first temperature distribution data and the second temperature distribution data.

### APPENDIX 16

The substrate processing method according to Appendix 15, in which the (d) includes
detecting a position of an outer edge of the substrate with respect to the substrate support based on the first temperature distribution data and the second temperature distribution data, and
detecting a relative position of the substrate with respect to a reference position of the substrate support based on the detected position of the outer edge of the substrate.

### APPENDIX 17

The substrate processing method according to Appendix 16, in which
the relative position includes an amount of mis-alignment and an angle of mis-alignment of a center of the substrate with respect to the reference position.

### APPENDIX 18

The substrate processing method according to any one of Appendices 15 to 17, further including:
(e) correcting the position of the substrate on the substrate support based on the relative position.

### APPENDIX 19

The substrate processing method according to Appendix 18, in which
the (e) includes re-placing the substrate on the substrate support by using a transfer device to correct the position of the substrate.

### APPENDIX 20

The substrate processing method according to any one of Appendices 15 to 19, in which
a plurality of temperature sensors are disposed in the substrate support.

### APPENDIX 21

The substrate processing method according to Appendix 20, in which
the substrate support has a substrate support surface configured to support the substrate,
the substrate support surface has a plurality of support regions, and
each of the plurality of temperature sensors is disposed in the substrate support in the respective support regions.

### APPENDIX 22

The substrate processing method according to Appendix 20 or 21, in which
each of the plurality of temperature sensors includes a resistor of which resistance value changes depending on a temperature, and
in the (a), power is supplied to each resistor of the plurality of temperature sensors, and the first temperature distribution data is acquired based on a voltage value of the power.

### APPENDIX 23

The substrate processing method according to Appendix 20 or 21, in which
each of the plurality of temperature sensors includes a resistor of which resistance value changes depending on a temperature, and
in the (c), power is supplied to each resistor of the plurality of temperature sensors, and the second temperature distribution data is acquired based on a voltage value of the power.

### APPENDIX 24

A substrate processing system including a substrate processing apparatus having a chamber and a substrate support disposed in the chamber, and a controller configured to execute
(a) a control of acquiring first temperature distribution data that includes a temperature distribution of the substrate support in a state in which a substrate is not placed,
(b) a control of placing the substrate on the substrate support,
(c) a control of acquiring second temperature distribution data that includes a temperature distribution of the substrate support in a state in which the substrate is placed, and
(d) a control of detecting a relative position of the substrate to the substrate support based on the first temperature distribution data and the second temperature distribution data.

The aforementioned embodiments have been described for illustration, and are not intended to limit the scope of the present disclosure. Various modifications may be made to the aforementioned embodiments without departing from the scope and gist of the present disclosure. For example, some elements in an embodiment may be added to another embodiment. Some components in an embodiment may be replaced with corresponding components in another embodiment.

1. A plasma processing method for generating plasma in a chamber to execute plasma processing on a substrate in a plasma processing apparatus having the chamber and a substrate support disposed in the chamber, the method comprising:
(a) placing the substrate on the substrate support;
(b) generating plasma in the chamber to execute the plasma processing on the substrate on the substrate support;
(c) acquiring data relating to ion flux generated between the plasma generated in the chamber and the substrate placed on the substrate support in the (b); and
(d) detecting an end point of the plasma processing based on the data.

2. The plasma processing method according to claim 1, wherein
the data related to the ion flux is data related to distribution of the ion flux.

3. The plasma processing method according to claim 1, wherein
the plasma processing includes etching processing for etching a film formed on the substrate, and
an end point of the etching processing is detected in the (d).

4. The plasma processing method according to claim 1, wherein
the (c) includes
(c-1) supplying power to each of a plurality of heaters disposed in the substrate support,
(c-2) acquiring the power supplied to each of the plurality of heaters in a state in which the plasma is generated in the chamber, and
(c-3) calculating the data based on the power acquired for each of the plurality of heaters in the (c-2).

5. The plasma processing method according to claim 4, wherein
the substrate support has a substrate support surface supporting the substrate,
the substrate support surface has a plurality of support regions, and
each of the plurality of heaters is disposed in the substrate support in the respective support regions.

6. A plasma processing apparatus comprising:
a chamber;
a substrate support disposed in the chamber; and
a controller having a processor and a memory with a computer readable program stored therein that upon execution of the computer readable program by the processor configures the controller to perform the following method:
(a) placing a substrate on the substrate support,
(b) generating plasma in the chamber to execute plasma processing on the substrate on the substrate support,
(c) acquiring data related to ion flux generated between the plasma generated in the chamber and the substrate placed on the substrate support in the (b),
(d) detecting an end point of the plasma processing based on the data, and
(e) stopping the generation of the plasma in the chamber in response to detecting the end point of the plasma processing.

7. A plasma processing method for generating plasma in a chamber to execute plasma processing on a substrate in a plasma processing apparatus having the chamber and a substrate support disposed in the chamber, the method comprising:
(a) placing the substrate on the substrate support;
(b) generating plasma in the chamber to execute the plasma processing on the substrate on the substrate support;
(c) acquiring distribution data that is data related to distribution of ion flux generated between the plasma and the substrate placed on the substrate support during a transitional period in which a state of the plasma generated in the chamber changes; and
(d) stopping the generation of the plasma in the chamber based on the acquired distribution data.

8. The plasma processing method according to claim 7, further comprising:
(e) determining whether there is an error in the state of the plasma during the transitional period based on the distribution data.

9. The plasma processing method according to claim 8, wherein
in the (e), a location where the error is found in the state of the plasma during the transitional period is identified based on the distribution data.

10. The plasma processing method according to claim 7, wherein
in the (c), a temporal change of the distribution data is acquired.

11. The plasma processing method according to claim 7, wherein
the transitional period includes at least one of start of plasma generation and switching between the steps of plasma processing.

12. The plasma processing method according to claim 7, wherein
the (c) includes:
(c-1) supplying power to each of a plurality of heaters disposed in the substrate support,
(c-2) acquiring the power supplied to each of the plurality of heaters in a state in which the plasma is generated in the chamber, and
(c-3) calculating the distribution data based on the power acquired for each of the plurality of heaters in the (c-2).

13. The plasma processing method according to claim 12, wherein
the substrate support has a substrate support surface configured to support the substrate,
the substrate support surface has a plurality of support regions, and
each of the plurality of heaters is disposed in the substrate support in the respective support regions.

14. A plasma processing apparatus comprising:
a chamber;
a substrate support disposed in the chamber; and
a controller having a processor and a memory with a computer readable program stored therein that upon execution of the computer readable program by the processor configures the controller to perform the following method:
(a) placing a substrate on the substrate support,
(b) generating plasma in the chamber to execute plasma processing on the substrate on the substrate support,
(c) acquiring distribution data that is data related to a distribution of ion flux generated between the plasma and the substrate placed on the substrate support during a transitional period in which a state of the plasma generated in the chamber changes, and
(d) stopping the generation of the plasma in the chamber based on the acquired distribution data.

15. The plasma processing apparatus according to claim 14, wherein
the method further comprising
(e) determining whether there is an error in the state of the plasma during the transitional period based on the distribution data.

16. The plasma processing apparatus according to claim 6, wherein
the data related to the ion flux is data related to distribution of the ion flux.

17. The plasma processing apparatus according to claim 6, wherein
the plasma processing includes etching processing for etching a film formed on the substrate, and
an end point of the etching processing is detected in the (d).

18. The plasma processing apparatus according to claim 6, wherein
the (c) includes:
(c-1) supplying power to each of a plurality of heaters disposed in the substrate support,
(c-2) acquiring the power supplied to each of the plurality of heaters in a state in which the plasma is generated in the chamber, and
(c-3) calculating the data based on the power acquired for each of the plurality of heaters in the (c-2).

19. The plasma processing apparatus according to claim 6, wherein
the substrate support has a substrate support surface supporting the substrate,
the substrate support surface has a plurality of support regions, and
each of the plurality of heaters is disposed in the substrate support in the respective support regions.

20. The plasma processing apparatus according to claim 6, wherein
the (c) includes acquiring the distribution data during a transitional period in which a state of the plasma generated in the chamber changes, and
the controller further performs
(e) determining whether there is an error in the state of the plasma during the transitional period based on the distribution data.
